(19) United States
(12) Patent Application Publication
(10) Pub. No.: US 2026/0219347 A1
(43) Pub. Date: Jul. 30, 2026

(54) METHOD AND SYSTEM FOR MEASURING EDDY CURRENTS GENERATED BY AN MRI SYSTEM COMPONENT

(71) Applicant: GE Precision Healthcare LLC, Waukesha, WI (US)

(72) Inventor: Seung-Kyun Lee, Cohoes, NY (US)

(73) Assignee: GE Precision Healthcare LLC, Waukesha, WI (US)

(21) Appl. No.: 19/039,282

(22) Filed: Jan. 28, 2025

(51) Int. Cl. G01R 33/565; G01R 33/385

(52) U.S. Cl. CPC G01R 33/56518; G01R 33/385

(57) ABSTRACT

A system and method for measuring gradient-induced eddy currents generated by an MRI system component configured to be located near an MRI gradient coil are provided. The system includes a current driver configured to deliver a driving current to the MRI gradient coil and a sensing coil array configured to measure an eddy current magnetic field from the MRI system component while the driving current is delivered. The sensing coil array comprises a plurality of pickup coils each configured to generate a voltage signal indicative of the eddy current magnetic field at a location of the respective pickup coil. One or more hardware processors are configured to characterize the eddy current magnetic field in the MRI system component based on the voltage signal generated by each of the plurality of pickup coils and the driving current delivered to the gradient coil. The eddy current magnetic field characterization is outputted.

### BACKGROUND

The present disclosure generally relates to magnetic resonance imaging systems, and specifically to systems and methods for measuring and characterizing the eddy currents generated by a component of the MRI system.

MR imaging (MRI) has proven useful in diagnosis of many diseases. MRI provides detailed images of soft tissues, abnormal tissues such as tumors, and other structures, which cannot be readily imaged by other imaging modalities, such as computed tomography (CT). Further, MRI operates without exposing patients to ionizing radiation experienced in modalities such as CT and x-rays. MRI is often used to obtain internal physiological information about a patient, including for brain imaging, thoracic imaging, spine imaging, cardiac imaging, and imaging other sections or tissues within a patient's body (anywhere on the patient). Additionally, many MRI systems enable multi-physiology or whole body imaging where a substantial portion of the patient's body is imaged, which is typically performed by separately imaging several portions of the patient's body and then stitching the images together to generate one continuous image.

MRI uses the nuclear magnetic resonance (“NMR”) phenomenon to produce images. When a substance such as human tissue is subjected to a uniform magnetic field, such as the so-called main magnetic field (polarizing field B₀) generated by an MRI system, the individual magnetic moments of the nuclei in the tissue attempt to align with this B₀ field, but precess about it in random order at their characteristic Larmor frequency. If the substance, or tissue, is subjected to a magnetic field (excitation field B1) which is in the x-y plane and which is near the Larmor frequency, the net aligned moment, or “longitudinal magnetization”, Mz, may be rotated, or “tipped”, into the x-y plane to produce a net transverse magnetic moment Mt. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients, sometimes referred to as readout gradients, phase-encoding gradients, or slice-selection gradients, vary according to the particular localization method being used. The resulting set of received signals are digitized and processed to reconstruct the image using reconstruction techniques. Eddy currents that are induced in electrically conductive MRI system components in or around the gradient coils can interfere with the gradient magnetic fields and thereby distort the images. Accurate spatial and temporal characterization of eddy current magnetic fields is important to reduce image distortions by post-processing, or devise hardware solutions to minimize eddy currents. Previous attempts for eddy current magnetic field characterization were either limited to low (0th and 1st-order) spatial orders through small number (<<10) of sensors, or only functional inside the MRI main magnet. The latter kind—methods relying on MRI magnet—can be further classified into image-based methods, and NMR field sensing (sometimes called field camera) methods. Importantly, both of these methods confound/mix the main magnet-generated eddy current fields with those generated by other MRI system components and make it difficult to isolate the latter such as eddy currents in gradient coils and RF components. Accordingly, the present invention addresses the need for a simple, cost-effective, and non-confounding method to characterize high spatial-order eddy currents in MRI system components that are not part of the main magnet.

### SUMMARY

This Summary is provided to introduce a selection of concepts that are further described below in the Detailed Description. This Summary is not intended to identify key or essential features of the claimed subject matter, nor is it intended to be used as an aid in limiting the scope of the claimed subject matter.

In one aspect of the disclosure, a system for measuring eddy currents generated by an MRI system component configured to be located in an MRI system during imaging is provided. The system includes a current driver configured to deliver a driving current to the MRI gradient coil adjacent to the system component of interest, and a sensing coil array configured to measure an eddy current magnetic field from the MRI system component while the driving current delivers/applies gradient magnetic field to the gradient coil. The MRI gradient coil may be a stand-alone coil that is outside of an MRI magnet. The sensing coil array comprises a plurality of pickup coils each configured to generate a voltage signal indicative of the eddy current magnetic field at a location of the respective pickup coil. One or more hardware processors are configured to characterize the eddy current magnetic field from the MRI system component based on the voltage signal generated by each of the plurality of pickup coils and the driving current delivered to the MRI gradient coil, and then output the eddy current magnetic field characterization.

In one embodiment, the system for measuring eddy currents is configured to characterize the eddy current magnetic field from the MRI system component when the MRI system component is in the gradient coil bore, or in the epoxy-encased gradient coil assembly itself, but not in the MRI main magnet.

In one embodiment, the eddy current magnetic field measured by the sensing coil array is generated by short time constant eddy currents. Optionally, the short time constant eddy currents have a time constant that is greater than 1 microsecond and less than 1 millisecond.

In one embodiment, characterizing the eddy current magnetic field includes determining spatial harmonic components of the eddy current magnetic field and a time constant or multiple time constants of each of the spatial harmonic components.

In another embodiment, characterizing the eddy current magnetic field includes determining at least one time constant of the eddy current magnetic field measured by each of the plurality of pickup coils.

In one embodiment, the one or more processors are further configured to determine a frequency response of each of the plurality of pickup coils based on the voltage signal and characterize the eddy current magnetic field based on the frequency response and the driving current delivered to the MRI gradient coil.

In one embodiment, the sensing coil array includes at least 10 pickup coils.

In one embodiment, the sensing coil array includes the plurality of pickup coils arranged in a circle.

In one embodiment, the MRI system component includes the gradient coil assembly, such as a head gradient coil or a body gradient coil, and/or a part thereof.

In other embodiments, the MRI system component includes an RF body coil or an RF shield.

In another aspect of the disclosure, a method for characterizing eddy currents generated by an MRI system component configured to be located in an MRI system during imaging is provided. The method includes delivering a driving current to the MRI gradient coil adjacent to the MRI system component to cause the MRI gradient coil to generate a primary magnetic field, wherein the primary magnetic field causes eddy currents in the MRI system component that generate an eddy current magnetic field, and measuring the eddy current magnetic field with a plurality of pickup coils. Each pickup coil is configured to generate a voltage signal indicative of the eddy current magnetic field at a location of the respective pickup coil. The eddy current magnetic field from the MRI system component is then characterized based on the voltage signal generated by each of the plurality of pickup coils and the driving current delivered to the MRI gradient coil. Note that the pickup coils can pick up both the primary magnetic field signal and the eddy current magnetic field signal. The former is separated from the latter by post-processing of the detected total signal based on their different temporal and frequency characteristics

In one embodiment, the primary magnetic field has a time constant of zero such that there is no time delay in this magnetic field with respect to the driving current. The eddy current magnetic field characterization is outputted and/or stored in a storage medium.

In one embodiment, the steps of delivering the driving current and measuring the eddy current magnetic field are conducted when the MRI system component is not located in the MRI main magnet.

In one embodiment, the method further includes determining a frequency response of each of the plurality of pickup coils based on the voltage signal and characterizing the eddy current magnetic field based on the frequency response and the driving current delivered to the MRI gradient coil.

In one embodiment, characterizing the eddy current magnetic field includes determining a spatial harmonic component of the eddy current magnetic field and one or more time constants of the spatial harmonic component.

In one embodiment, characterizing the eddy current magnetic field includes determining one of more time constants of the eddy current magnetic field measured by each of the plurality of pickup coils.

In one embodiment, the MRI system component is a gradient coil assembly configured to be placed in a bore of the MRI system and the method further includes driving the gradient coil to generate each of an x-axis gradient field, a y-axis gradient field, and a z-axis gradient field and measuring the eddy current magnetic field from the MRI system component with the plurality of pickup coils for each of the x-axis gradient field, the y-axis gradient field, and the z-axis gradient field. The eddy current magnetic field from the MRI system component is separately characterized for each of the x-axis gradient field, the y-axis gradient field, and the z-axis gradient field based on the measurements taken when that field was being generated.

In one embodiment, the method further includes rotating the plurality of pickup coils to a plurality of rotational positions within the MRI system component and receiving the voltage signal from each of the plurality of pickup coils at each of the plurality of rotational positions as plurality of sensing coils are rotated about an axis. The eddy current magnetic field is then characterized based on the voltage signal from each of the plurality of pickup coils at each of the plurality of rotational positions.

Various other features, objects, and advantages of the invention will be made apparent from the following description taken together with the drawings.

### BRIEF DESCRIPTION OF THE DRAWINGS

The present disclosure is described with reference to the following Figures.

FIG. 1 is a schematic diagram of an MRI system, in accordance with an exemplary embodiment.

FIG. 2 illustrates one embodiment of a system for characterizing eddy currents generated by an MRI system component according to one embodiment of the present disclosure.

FIG. 3 illustrates one embodiment of a sensing coil array according to one embodiment of the present disclosure.

FIG. 4 illustrates the sensing coil array of FIG. 3 in use measuring an eddy current magnetic field from an MRI system component, which here is a gradient coil assembly.

FIGS. 5A and 5B are logic flow charts illustrating exemplary methods of processing measurement data from a sensing coil array to characterize an eddy current magnetic field.

FIGS. 6A and 6B illustrate measurement data shown in the frequency domain.

FIGS. 7-11 are graphs illustrating various processing steps for characterizing the eddy current magnetic field based on measurement data from a plurality of pickup coils in a sensing coil array.

FIG. 12 illustrates one embodiment of a method of measuring and characterizing the eddy current magnetic fields for a gradient coil assembly.

### DETAILED DESCRIPTION

In the present description, certain terms have been used for brevity, clarity and understanding. No unnecessary limitations are to be inferred therefrom beyond the requirement of the prior art because such terms are used for descriptive purposes only and are intended to be broadly construed.

As used herein, unless otherwise limited or defined, discussion of particular directions is provided by example only, with regard to particular embodiments or relevant illustrations. For example, discussion of “top,” “bottom,” “front,” “rear,” “left,” “right,” “horizontal,” “vertical,” and “longitudinal” features and/or relative motion, e.g., movement “up” and “down,” is generally intended as a description only of the orientation of such features relative to a reference frame of a particular example or illustration. Correspondingly, for example, a “top” feature may sometimes be disposed below a “bottom” feature (and so on), in some arrangements or embodiments. Additionally or alternatively, embodiments may be arranged in a different orientation such that “top” and “bottom” features are arranged horizontally relative to each other, for example in a “left-to-right” orientation.

The use herein of the terms “including,” “comprising,” or “having,” and variations thereof, is meant to encompass the elements listed thereafter and equivalents thereof, as well as additional elements. Embodiments recited as “including,” “comprising,” or “having” certain elements are also contemplated as “consisting essentially of” and “consisting of” those certain elements.

The inventor has recognized that systems and methods are needed for characterizing the eddy current behavior of the gradient system of an MRI system and other removable components that are placed in an MRI system apart from and outside of the main magnetic field generated by the main magnet. Such components of the MRI system for which it may be desirable to individually characterize eddy current behavior include gradient coils and gradient coil assemblies (such as the head gradient coil or the body gradient coil and/or the metallic parts thereof), RF body coils, RF shields, RF receiver coils, or the like.

The inventor has recognized that characterizing the eddy current behavior of such MRI system components outside of the influence of the main magnetic field enables improved eddy current compensation for image reconstruction, particularly for spiral or echo planar imaging (EPI). Existing NMR-based dynamic field mapping devices and systems are tuned to the Larmor frequency and cannot be used outside the main magnet. Measuring gradient eddy currents outside of the main magnetic field is useful to discern eddy current sources within the gradient coil and RF components, independent of contributions from the cryostat.

Measurement and characterization of eddy current behavior of an individual component also enables improved component design where MRI system components can be designed to minimize eddy currents and thus to minimize image distortion caused by eddy currents. For example, measurement and characterization of eddy current behavior can lead to improved gradient coil design and better compensation for gradient coil eddy currents in image reconstruction to reduce the image-distorting effects. Accordingly, the eddy current magnetic field characterization may be utilized in image reconstruction to compensate for the eddy current magnetic field and remove or reduce the image-distorting effects thereof.

The gradient system is an essential component of an MRI system. It performs spatial and temporal encoding of transverse magnetization through a spatially grading magnetic field. Gradient waveforms can be synthesized to perform a range of encoding strategies including conventional Cartesian image encoding, as well as non-Cartesian acquisitions such as radial and spiral. Despite generally being considered so, the gradient fields used for spatial encoding in clinical MRI systems are never truly linear over the imaging field-of-view (“FOV”). There are many technical factors that inevitably cause distortions in the realized gradient magnetic field, including eddy currents, mechanical/thermal vibrations, and physiologically induced magnetic fields, to name a few. These unwanted gradient distortions present an engineering challenge to realizing the actual gradient field relative to the prescribed gradient. Differences between the prescribed gradients and the actual gradients result in image artifacts, including blurriness, ringing, or phase error, to name a few.

Certain MRI techniques are more prone to gradient distortions and images that suffer from gradient distortions. For example, gradient distortions can be a critical issue in rapid image acquisition techniques, such as echo planar imaging (EPI). In these cases, the k-space trajectory is prone to deviation from the prescribed trajectory due to the accumulated error in the phase evolution in the distorted gradient. In addition, time-varying large gradient amplitudes generate time-varying concomitant gradients that are another source of error that distorts k-space trajectory.

The disclosed systems and methods were developed in view of the problems caused by eddy currents in MRI, which are well known in the relevant art, and in view of the need for isolated component eddy current measurement and characterization recognized by the inventor. The disclosed system and method utilize a sensing coil array for spatio-temporal mapping of eddy current magnetic fields from an MRI system component when it is located apart from the main magnet, such as in a standalone gradient coil. For example, the sensing coil array may comprise over 20 untuned inductive pickup coils arranged in a circle. The sensing coil array is placed on or in the MRI system component and measure the eddy current magnetic field while a driving current is delivered to an MRI gradient coil. In one exemplary implementation, the sensing coil is configured to be placed in the center of the measurement area of a head gradient coil or a body gradient coil and to measure the eddy current magnetic field while the gradient coil generates each of an x-axis gradient field (G_{X}), a y-axis gradient field (G_{Y}), and a z-axis gradient field (G_{Z}).

The system then processes the output of the sensing coil array and characterizes the eddy current behavior for each gradient field axis. In one embodiment, the measurement is based on broadband frequency response function (FRF) converted to time-domain step response. The eddy current magnetic field is then characterized, such as by identifying a dominant spherical harmonic shape or other spatial harmonic component of the computed time-domain eddy current magnetic fields and their spatial harmonic decomposition.

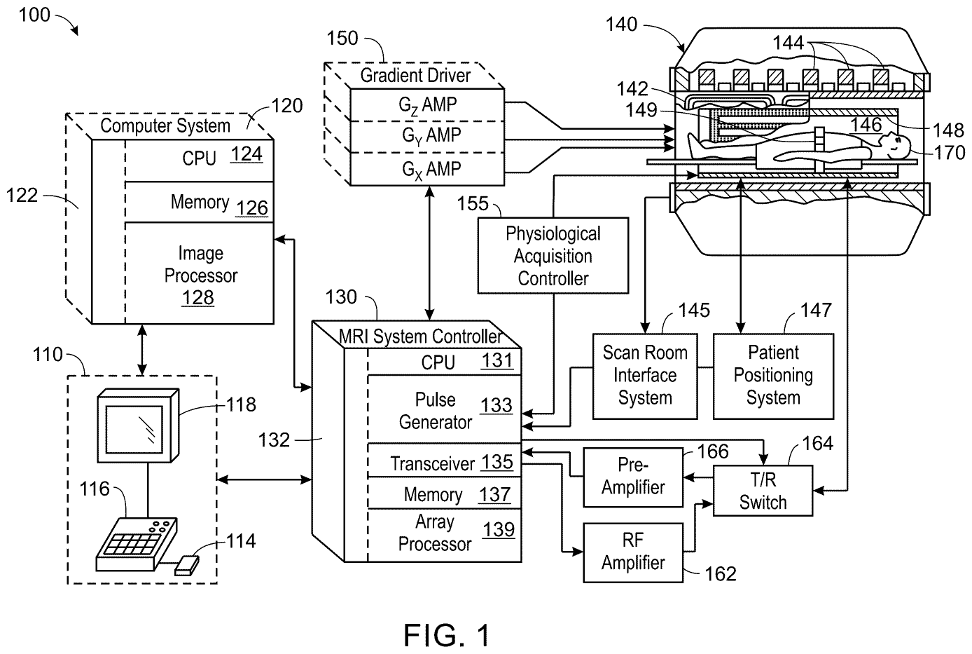

Referring to FIG. 1, a schematic diagram of an exemplary MRI system 100 is shown in accordance with an embodiment. The operation of MRI system 100 is controlled from an operator workstation 110 that includes an input device 114, a control panel 116, and a display 118. The input device 114 may be a joystick, keyboard, mouse, track ball, touch activated screen, voice control, or any similar or equivalent input device. The control panel 116 may include a keyboard, touch activated screen, voice control, buttons, sliders, or any similar or equivalent control device. The operator workstation 110 is coupled to and communicates with a computer system 120 that enables an operator to control the production and viewing of images on display 118. The computer system 120 includes a plurality of components that communicate with each other via electrical and/or data connections 122. The computer system connections 122 may be direct wired connections, fiber optic connections, wireless communication links, or the like. The components of the computer system 120 include a central processing unit (CPU) 124, a memory 126, which may include a frame buffer for storing image data, and an image processor 128. In an alternative embodiment, the image processor 128 may be replaced by image processing functionality implemented in the CPU 124. The computer system 120 may be connected to archival media devices, permanent or back-up memory storage, or a network. The computer system 120 is coupled to and communicates with a separate MRI system controller 130.

The MRI system controller 130 includes a set of components in communication with each other via electrical and/or data connections 132. The MRI system controller connections 132 may be direct wired connections, fiber optic connections, wireless communication links, or the like. The components of the MRI system controller 130 include a CPU 131, a pulse generator 133, which is coupled to and communicates with the operator workstation 110, a transceiver 135, a memory 137, and an array processor 139. In an alternative embodiment, the pulse generator 133 may be integrated into a resonance assembly 140 of the MRI system 100. The MRI system controller 130 is coupled to and receives commands from the operator workstation 110 to indicate the MRI scan sequence to be performed during an MRI scan. The MRI system controller 130 is also coupled to and communicates with a gradient driver system 150, which is coupled to a gradient coil assembly 142 to produce magnetic field gradients during an MRI scan.

The pulse generator 133 may also receive data from a physiological acquisition controller 155 that receives signals from a plurality of different sensors connected to an object or patient 170 undergoing an MRI scan, including electrocardiography (ECG) signals from electrodes attached to the patient 170. And finally, the pulse generator 133 is coupled to and communicates with a scan room interface system 145, which receives signals from various sensors associated with the condition of the resonance assembly 140. The scan room interface system 145 is also coupled to and communicates with a patient positioning system 147, which sends and receives signals to control movement of a table 171. The table 171 is controllable to move the patient in and out of the core 146 and to move the patient to a desired position within the core 146 for an MRI scan.

The MRI system controller 130 provides gradient waveforms to the gradient driver system 150, which includes, among others, G_{X}, G_{Y} and G_{Z} amplifiers. Each G_{X}, G_{Y} and G_{Z} gradient amplifier excites a corresponding gradient coil in the gradient coil assembly 142 to produce magnetic field gradients used for spatially encoding MR signals during an MRI scan. The gradient coil assembly 142 is included within the resonance assembly 140, which also includes a superconducting magnet (the “main magnet”) having superconducting coils 144, which in operation, provides a homogenous longitudinal magnetic field B₀ throughout a core 146, or open cylindrical imaging volume, that is enclosed by the resonance assembly 140. The resonance assembly 140 also includes a RF body coil 148 which in operation, provides a transverse magnetic field B₁ that is generally perpendicular to B₀ throughout the core 146. The resonance assembly 140 may also include RF surface coils 149 used for imaging different anatomies of a patient undergoing an MRI scan. The RF body coil 148 and RF surface coils 149 may be configured to operate in a transmit and receive mode, transmit mode, or receive mode.

An object or patient 170 undergoing an MRI scan may be positioned within the core 146 of the resonance assembly 140. The transceiver 135 in the MRI system controller 130 produces RF excitation pulses that are amplified by an RF amplifier 162 and provided to the RF body coil 148 and RF surface coils 149 through a transmit/receive switch (T/R switch) 164.

As mentioned above, RF body coil 148 and RF surface coils 149 may be used to transmit RF excitation pulses and/or to receive resulting MR signals from a patient undergoing an MRI scan. The resulting MR signals emitted by excited nuclei in the patient undergoing an MRI scan may be sensed and received by the RF body coil 148 or RF surface coils 149 and sent back through the T/R switch 164 to a pre-amplifier 166. The amplified MR signals are demodulated, filtered and digitized in the receiver section of the transceiver 135. The T/R switch 164 is controlled by a signal from the pulse generator 133 to electrically connect the RF amplifier 162 to the RF body coil 148 during the transmit mode and connect the pre-amplifier 166 to the RF body coil 148 during the receive mode. The T/R switch 164 may also enable RF surface coils 149 to be used in either the transmit mode or receive mode.

The resulting MR signals sensed and received by the RF body coil 148 are digitized by the transceiver 135 and transferred to the memory 137 in the MRI system controller 130.

A MR scan is complete when an array of raw k-space data, corresponding to the received MR signals, has been acquired and stored temporarily in the memory 137 until the data is subsequently transformed to create images. This raw k-space data is rearranged into separate k-space data arrays for each image to be reconstructed, and each of these separate k-space data arrays is input to the array processor 139, which operates to Fourier transform the data into arrays of image data.

The array processor 139 uses a known transformation method, most commonly a Fourier transform, to create images from the received MR signals. These images are communicated to the computer system 120 where they are stored in memory 126. In response to commands received from the operator workstation 110, the image data may be archived in long-term storage or it may be further processed by the image processor 128 and conveyed to the operator workstation 110 for presentation on the display 118.

In various embodiments, the components of computer system 120 and MRI system controller 130 may be implemented on the same computer system or a plurality of computer systems. Similarly, each of the computer system 120 and MRI system controller 130 may be implemented using a single processor, or multiple processors networked together or otherwise communicatively connected.

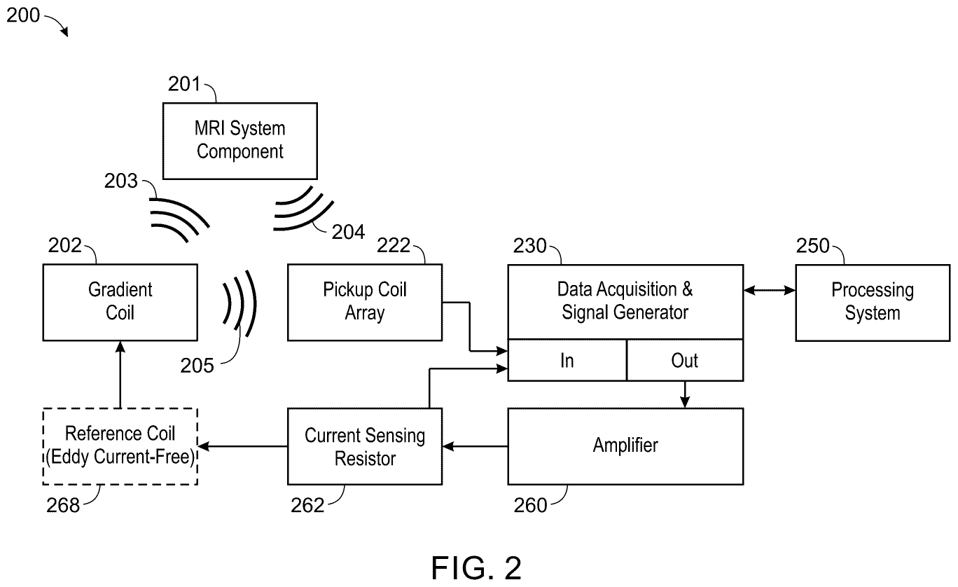

FIG. 2 depicts one embodiment of a system 200 for characterizing eddy currents generated by an MRI system component 201 when driven by a gradient coil 202 such as a head gradient coil, body gradient coil, etc. The component 201 may be any part of the MRI system for which it may be desirable to individually characterize eddy current behavior, such as and including gradient coil itself, RF body coils, RF shields, RF receiver coils, interventional devices, or the like. The system 200 is configured to measure and characterize time-varying eddy currents when the component 201 is apart from and not in the presence of the main magnetic field generated by the main magnet (see magnet 144 in FIG. 1). Thus, the system is configured to measure and characterize the eddy current contribution that the component 201 will introduce into the MRI system 100 once that component is utilized in imaging, such as placed in the bore.

The system 200 is particularly sensitive to measure and characterize with high signal-to-noise ratio short time constant eddy currents, such as eddy currents with a time constant that is less than or equal to about 1 millisecond (or, in some embodiments, up to a few milliseconds). For example, the system may be configured to measure and characterize eddy current magnetic fields with time constants between 1 microsecond and 1 millisecond.

The eddy current characterization can then be used for various image reconstruction, sequence design, and/or product (protocol) selection purposes. For example, the eddy current characterization can be compensated for in image reconstruction to improve image quality. Alternatively or additionally, the eddy current information can be used to inform a clinician regarding component selection for certain imaging modalities (e.g., where possible, to avoid using certain imaging modalities that are susceptible to short time constant eddy currents, such as EPI). Alternatively or additionally, the eddy current information can be used in product development to improve component design to reduce eddy currents (or at least reduce the types of eddy currents that most negatively impact imaging).

The MRI system component 201 generates eddy current field (204) in response to the driving gradient coil 202 which generates a gradient field 203. The pickup coil array 222 detects both the primary gradient field 205, and the secondary eddy current field 204 that reach the array. In some cases, the MRI system component 201 can be the gradient coil 202 itself, in which case the measured field 204 is the gradient coil's self-generated eddy current field.

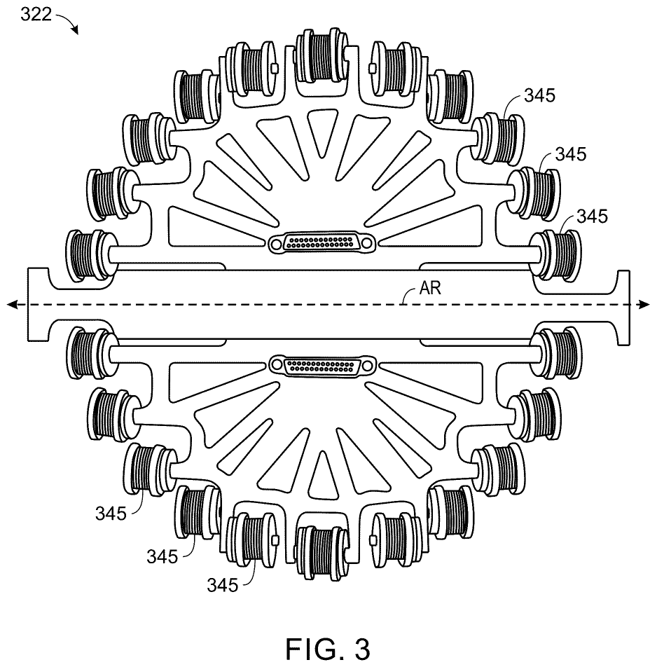

The sensing coil array 222 is configured to be placed near the component 201, such as in area with respect to the patient where the imaged portion of the patient would be located so as to measure the eddy current behavior of the component at the location that would most impact imaging. The sensing coil array 222, which is exemplified and discussed more with respect to FIG. 3, is configured to generate voltage signals indicative of the eddy current magnetic field at a plurality of sensing locations of the pickup coils in the array. The voltage signals are received and processed to characterize the eddy current magnetic field for the component 201. Here, the voltage signals from the sensing coil array 222 are received by the data acquisition and signal generator system 230, which digitizes the analog voltage signals and/or performs preliminary signal conditioning and/or processing (such as via an analog front end) and then provides the raw digitized sensor data to the processing system 250 which executes logic to characterize the eddy currents as described herein.

In this embodiment, the driving current signals for driving the MRI gradient coil, and thereby inductively driving the MRI system component, are generated by the data acquisition and signal generator system 230. For example, the driving current signal may be a pseudo white-noise waveform (bandwidth/resolution=12,000/20 Hz) that generate the primary magnetic field (e.g., causing the gradient coil to generate x, y, or z gradient field), for broad-band testing. In other embodiments, the driving current may be any periodic or pulsed current signal as is appropriate for testing the particular component and to replicate the driving of that component during normal imaging. The driving current signal is amplified by the amplifier 260. In one embodiment, the amplifier may be a low-power audio amplifier. The amplified driving current signal is measured by a current sensing resistor 262, and the measured signal is provided as an input to the data acquisition device 230 and/or the processing system 250. In other embodiments, the driving current may be measured or determined by other means. Those two inputs—the eddy current magnetic field measurement and the driving current measurement, are then utilized by the processing system 250 to characterize the eddy current behavior of the component. In some embodiments, the eddy currents may be measured in a 3-dimensional space, such as by rotating the sensing array, and a 3-D characterization of the eddy current magnetic field may be generated. Alternatively, the eddy current magnetic field may only be measured in one plane, and the eddy current characterization may describe just the planar measurement of the magnetic field or the planar measurement may be extrapolated to determine a 3D characterization based on measurements in one plane and spatial harmonic decomposition.

The example in FIG. 2 includes a reference coil 268, which is an eddy current-free reference coil connected in series with the gradient coil in the driving circuit. The reference coil 268 is configured to act as a zeroing or reference to verify that the measurement performed by the sensing coil array 222 is not spoiled. Thus, the reference coil is arranged so that it does not produce any eddy currents, such as placed on a wooden block and out of range of other metal components. The sensing coil array 222 is placed on or near the reference coil 268 while the driving current is provided to the reference coil 268, and when in that position should measure zero eddy currents (or no eddy current magnetic field). In other embodiments, the reference coil 268 may not be in series, such as on a separate driving circuit such that the driving current may be driven by other means. In still other embodiments, the reference coil 268 may be eliminated.

The arrangement of devices in FIG. 2 is merely exemplary. While the depicted embodiment shows a combined data acquisition and signal generator system 230, in other embodiments, the signal generator may be a separate device from the data acquisition system. In some embodiments, the data acquisition system may be combined with the processing system 250.

FIG. 3 illustrates one embodiment of a sensing coil array 322. The sensing coil array 322 includes a plurality of pickup coils 345 arranged to cover a measurement area. The depicted embodiment includes 22 pickup coils 345 arranged in a circle. In other embodiments, the sensing coil array 322 may include a different number of pickup coils, such as at least 10 pickup coils 345. In other embodiments, the sensing coil array 322 may include at least 20 pickup coils 345. In other embodiments, the sensing coil array 322 may include at least 30 pickup coils 345.

The pickup coils 345 are configured to generate a voltage signal in response to the eddy current magnetic fields. The pickup coils 345 may all be copper wire-wound solenoids. To provide just one example, the pickup coils 345 may be formed by 200 windings, have an effective area (A_{eff}) of 0.0463 m², an outer diameter of 22 mm, and a length of 10 mm. In other embodiments, the pickup coils 345 may have fewer or more windings and may be larger or smaller. Larger pickup coils with more windings can increase the field sensitivity, but reduces spatial accuracy as it samples the field over a larger sensitive volume.

The pickup coils 345 may be arranged in a plane, as shown, which in some embodiments may be arranged in a different shape other than a circle, such as an oval or a square. The pickup coils 345 may be arranged in a plane and may be distributed symmetrically about an axis of rotation AR running through the center of the sensing coil array 322, as is illustrated. The sensing coil array 322 may be rotated 180 degrees to measurement positions distributed about a sphere. Alternatively, the pickup coils 345 may be arranged on one side of the axis AR, such as in an arc, and the sensing coil array may be rotated 360 degrees to measure the spherical space. In still other embodiments, the pickup coils 345 may be arranged in a 3D spherical shape so as to simultaneously conduct measurements at positions around the spherical volume or other volumetric shape.

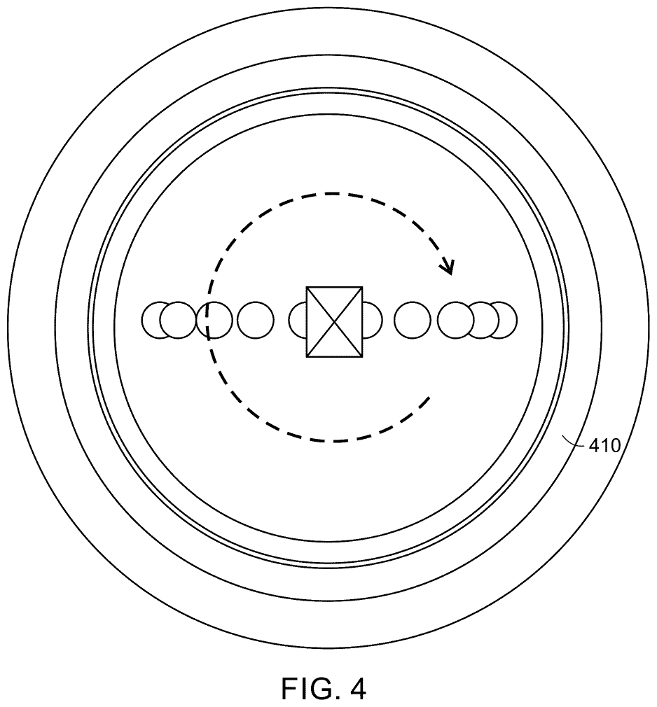

The sensing coil array 322 may be sized and arranged according to the size and shape of the component being measured, which may dictate the number and shape arrangement of the pickup coils 345. In the depicted example, the sensing coil array has a diameter of 26 cm and is configured to fit in a head gradient coil or a body gradient coil. FIG. 4 shows the sensing array 322 shown in FIG. 3 positioned in a head gradient coil 410, and specifically located where the head measurement would occur if the coil were used for patient imaging. The sensing array 322 is oriented such that the pickup coils 345 are arranged in the x-z plane. Where 3D spatial measurement is conducted, the array 322 is rotated about rotational axis AR which is perpendicular to the page. In another embodiment, the rotational axis AR may be in the same plane but perpendicular to that shown. In still another implementation the sensing array 322 may be situated in a different starting orientation, such as in the x-y plane, and the rotational axis AR may be vertically perpendicular to that shown.

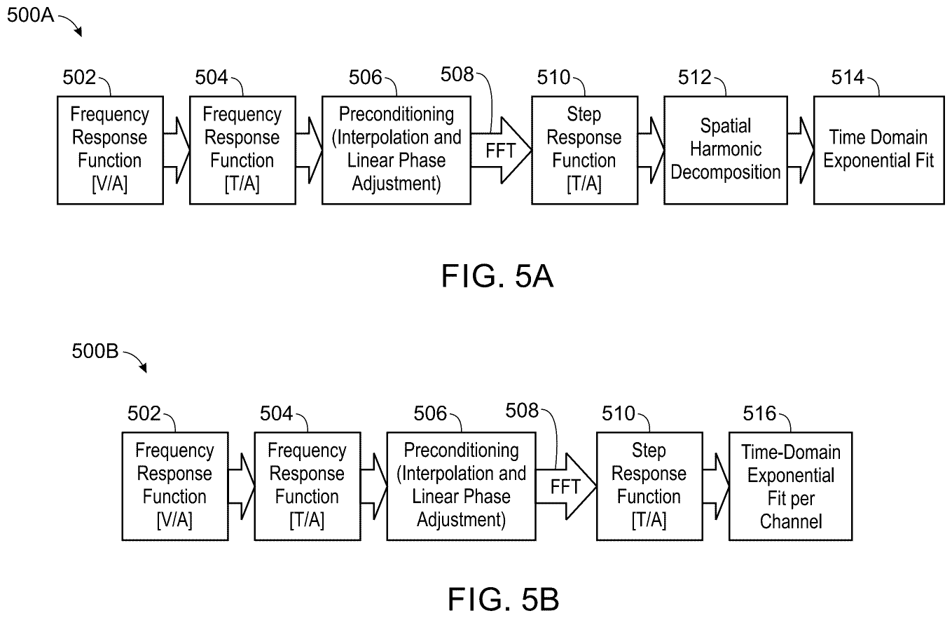

The voltage output from the pickup coils 345 is then processed, such as by the processing system 250 (FIG. 2) to characterize the eddy current magnetic field measured by the sensor coil array 322. FIGS. 5A and 5B are logic diagrams depicting embodiments of such processing logic. In FIG. 5A, the characterization involves spatial harmonic decomposition is performed to identify one or more harmonic components, or spatial harmonic shapes, and the time constant of the respective spatial harmonic component(s). In FIG. 5B, the characterization involves time-domain exponential fit to determine the time constant of the eddy current magnetic field measured by each pickup coil.

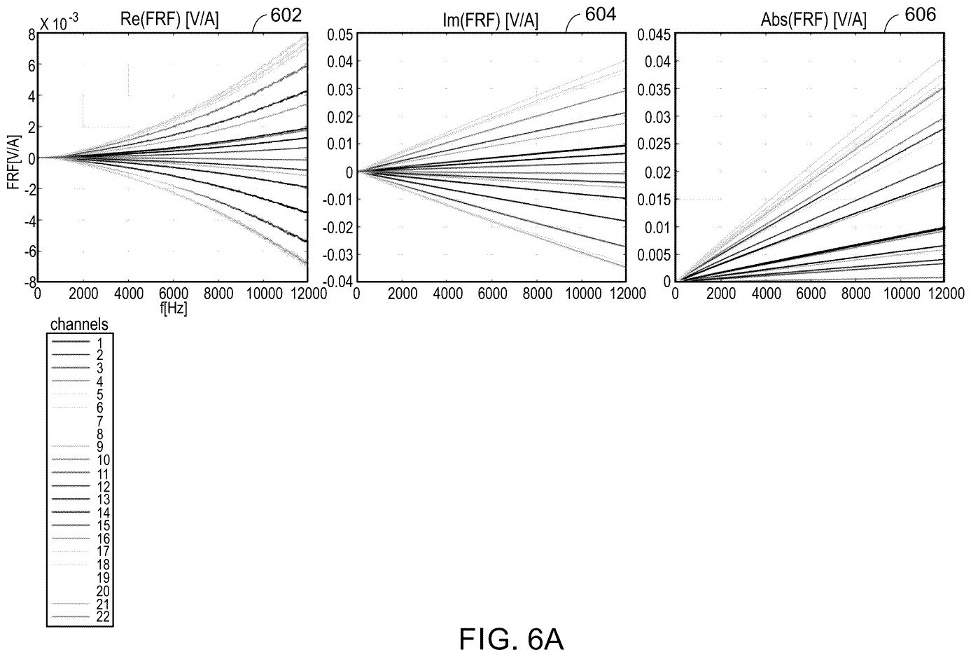

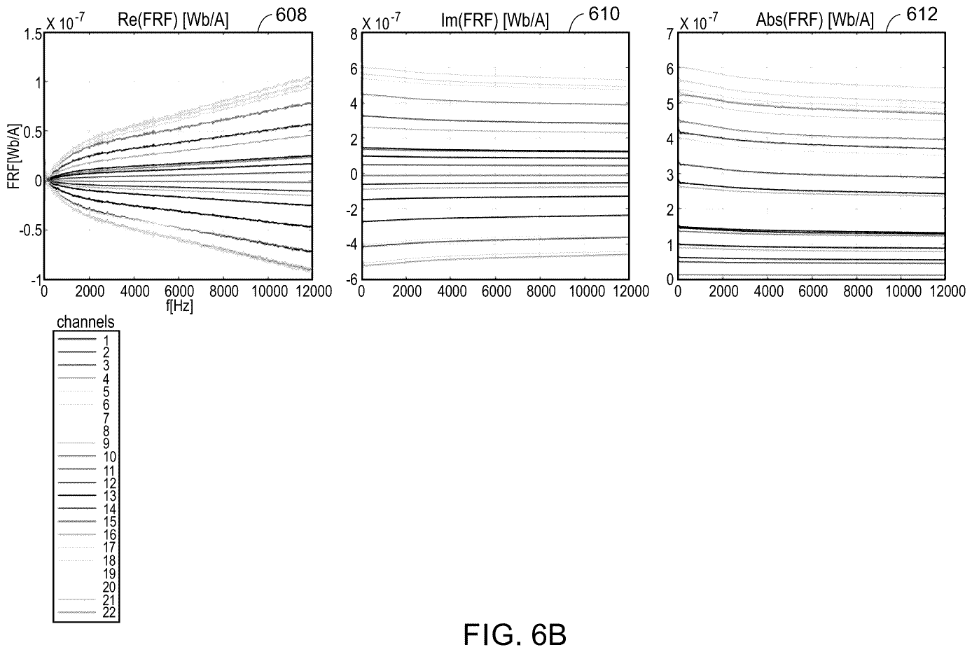

In both FIGS. 5A and 5B, the processing method starts by computing a frequency response function at step 502 to convert the time-domain voltage data into spectral data describing the complex (i.e., having both real and imaginary components) frequency response of the measured eddy current magnetic field in volts per amp (V/A). Preferably, the frequency response function (FRF) satisfies Hermitian symmetry and Kramers-Kronig relationship. FIG. 6A shows an exemplary raw frequency domain data, which is a complex frequency response, determined from the voltage signal from each of 22 pickup coils (i.e., using the sensor coil array 322 embodiment shown in FIG. 3) at a given measurement position. Graph 602 shows the in-phase (“real”) component of the frequency response in each pickup coil, the middle graph 604 shows the out-of-phase (imaginary) component of the frequency response, and the right graph 606 shows the absolute value of the complex frequency response. FIG. 6B shows the magnetic flux values in Weber (Wb) per amp. The real component of the data from each of the 22 pickup coils is shown in graph 608. The imaginary component of each is shown in graph 610, and the absolute value of the complex values is shown in graph 612.

The frequency response data is scaled at step 504 such that it is converted into Tesla per amp (T/A). The conversion comes from the property of the pickup coil (effective area, A_{eff}) and the frequency f. Preconditioning of the raw frequency domain data is performed at step 506, which consists of interpolation in the frequency domain to smooth out any gaps in the data, and/or applying a filter to minimize phase discontinuity at the frequency end points. Preconditioning ensures continuity of FRF at DC and at frequency boundaries.

The frequency response data is then converted to a step response function at steps 508 and 510. A Fast Fourier Transform is performed at step 508 to convert the frequency domain data to time domain data. To recapitulate the processing workflow from step 502, measured voltage FRF is first converted to the magnetic field FRF by division by 2πf A_{eff}. The resulting B-field FRF is a set of complex ratios F(fₙ)=B(fₙ)/I(fₙ) between the input current I and output field B at N discrete frequencies, fₙ=n·df, n=0, 1, . . . , N−1. Double-sided spectrum and cyclic frequency convention are assumed: −ndf⇔(N−n)df. An impulse at t=0 ~dt with unity amplitude I=1 [A] corresponds to I(fₙ)=1/N [A] for all n, the response (=impulse response) to which is the summation of exp(2πi fₙt) multiplied by F(fₙ)/N. This equals the inverse Fourier transform of the B-field FRF. Applying cumulative sum to this yields the desired step-function response in [T/A] in step 510.

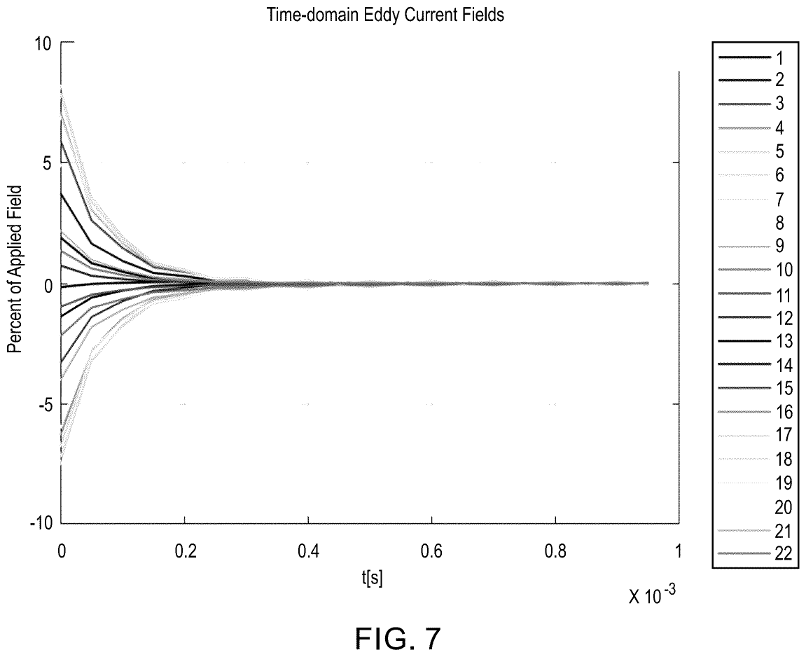

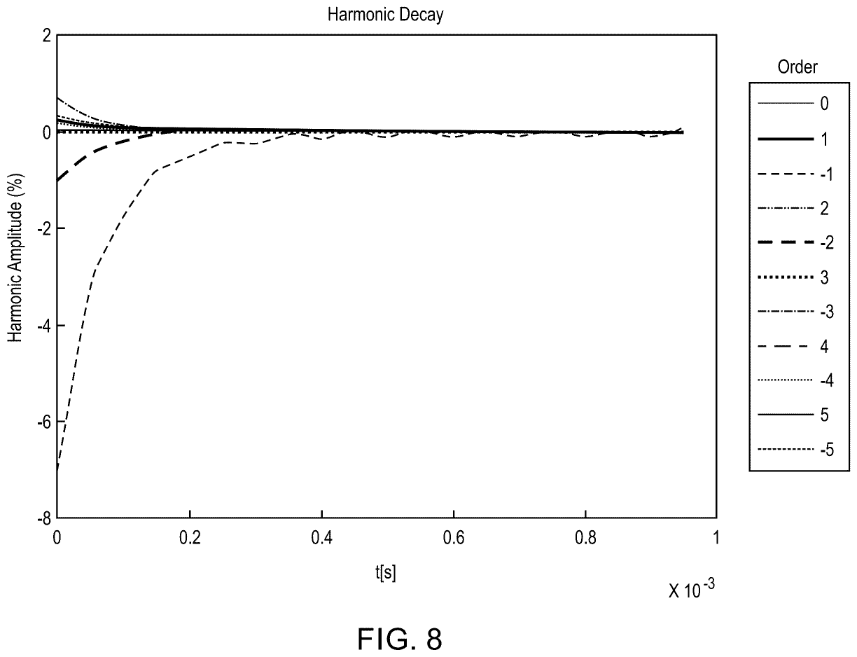

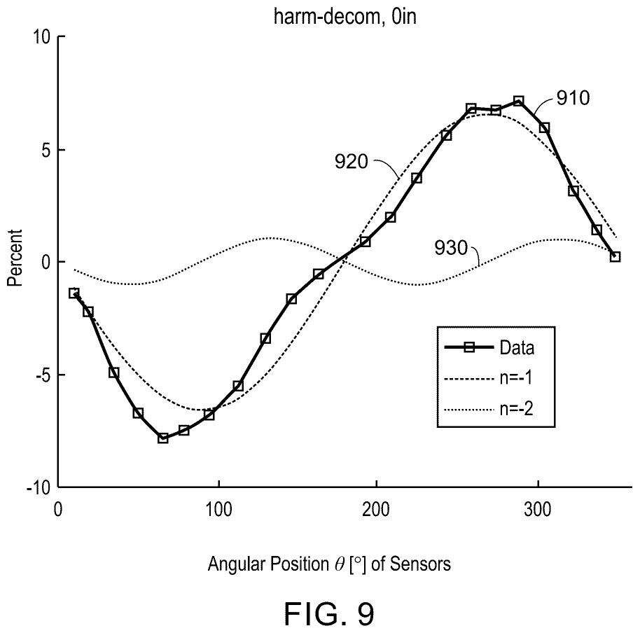

The remaining two steps in FIGS. 5A and 5B diverge and produce different characterization values of the eddy current magnetic field measurements. In FIG. 5A, spatial harmonic decomposition is performed to identify the spatial harmonic components, or dominant spherical harmonic shapes. A time domain exponential fit is then used to determine the time constant of one or more of the spatial harmonic components. The identified spatial harmonic component, and the amplitude and/or time constant thereof, may then be outputted as the values characterizing the eddy current magnetic field in that measurement setup. FIGS. 7 and 8 illustrate this concept for the data illustrated in FIGS. 6A and 6B. FIG. 7 shows computed time-domain eddy current field measurements picked up by each of the 22 pickup coils. Each sensor exhibits a different magnitude and time constant of exponential decay. FIG. 8 illustrates the spatial harmonic components from 0th order through 5^{th} order harmonics. As illustrated, there are two main harmonic components, with the first and second-order harmonics (−1 and −2) being dominant (see FIG. 9). As shown in the graph, the amplitude of the −1 order harmonic decays from −7 to −1 in about 0.2 ms.

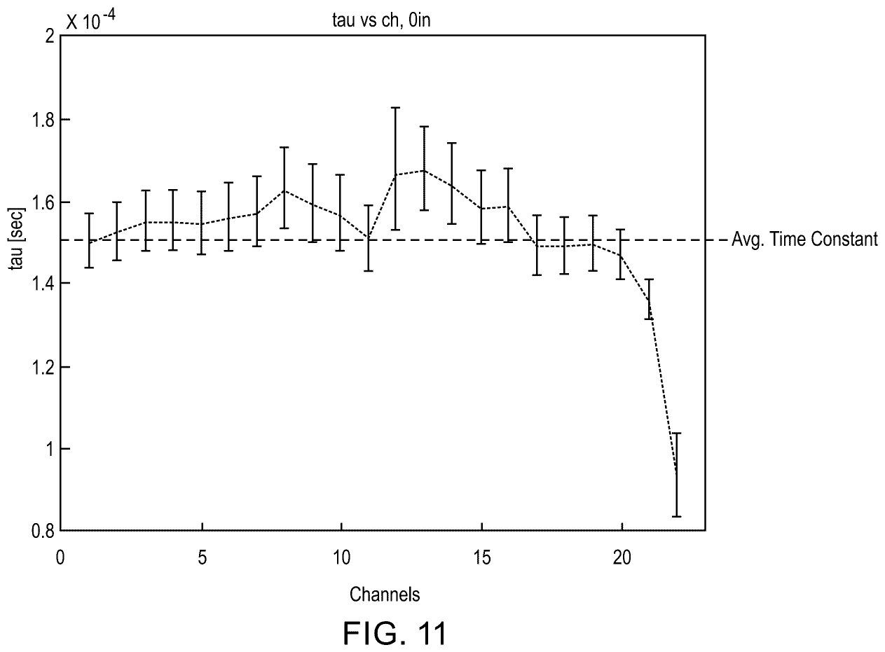

Turning back to FIG. 5B, another method of characterizing the magnetic field is characterizing each sensor response, rather than the harmonic component response illustrated in FIGS. 5A and 8. Here, temporal time domain fitting is performed at step 516. Thus, the exponential fitting is performed on the time-domain data from each pickup coil to determine the time constant for the eddy current magnetic field magnitude measured by each of the pickup coils, as the data exemplified in FIG. 7 and FIG. 11 for each of the 22 pickup coils. This method characterizes temporal eddy current field characteristics in localized regions.

FIGS. 9-11 illustrate exemplary output characterization values for an exemplary coil sensor array comprising multiple pickup coils at a given measurement orientation. FIG. 9 shows the time domain response amplitude as a function of the position of each of the 22 pickup coils around the sensor array (represented as angular position between 0 and 360 degrees around the center point of the sensor coil array). Line 910 is formed based on the plotted magnitude of the eddy current magnetic field measurement for each sensor, where the 22 points represent the magnitude value of the raw data for each of the 22 sensors at a particular measurement orientation of the sensor coil array. Lines 920 and 930 show the two dominant sine wave components of the wave formation of line 910 (illustrated as a linear combination analysis).

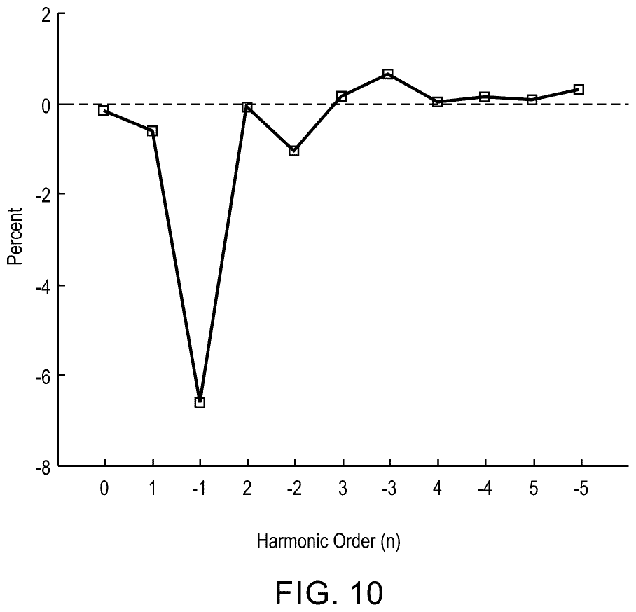

FIG. 10 illustrates the results of spatial harmonic decomposition of the time-domain data (points on line 910), showing the harmonic amplitudes plotted as a function of harmonic order. As can be seen from the graph, there are two main harmonic components (−1 and −2 harmonics). These dominant harmonic components correspond to the sine wave components represented by lines 920 and 930 in FIG. 9.

FIG. 11 exemplifies an output of the time constant values shown in FIG. 5B, where temporal analysis is performed without spatial harmonic analysis. The graph shows time constant values for the eddy current magnetic field measurements by each of the plurality of pickup coils. Namely, the 22 time constant values represent the time constant identified for each of the 22 pickup coils in the exemplary embodiment of the sensor array illustrated in FIG. 3 and throughout. An average time constant is also calculated, which here is equal to about 150 microseconds.

The steps in FIGS. 5A and 5B may be used in the alternative, or may be used together to provide multiple characterization values for the eddy current magnetic fields using the logic illustrated in steps 512 and 514, as well as step 516. Where multiple measurements are made in a 3D volume, the eddy current characterization values at each of the measurement locations or orientations may be summarized for the volume. For example, the spatial harmonic component(s) and time constant values may be provided across the volume based on the values determined at each measurement orientation. Similarly, the time constant values for the sensor magnitudes may be provided across the volume based on the values determined at each measurement location and orientation.

The time-domain exponential fit of 514 and 516 of FIGS. 5A and 5B may include single exponential fitting or multi-exponential fitting to determine one or more time constants, respectively. The resulting time constants can be less than 1 ms, 10 ms, 100 ms, or larger than 100 ms. Because of the sensitivity characteristic of inductive pickup coils, shorter time constant components can be determined with higher signal-to-noise ratio.

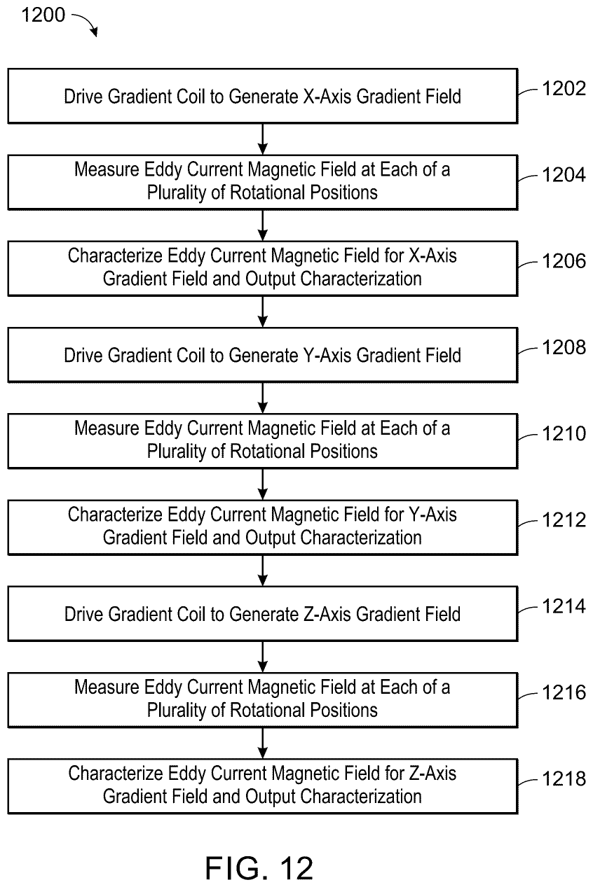

FIG. 12 illustrates method steps for characterizing eddy currents generated by an MRI system component, and specifically for a gradient coil wherein each of the x, y, and z gradient fields are characterized. A driving current is delivered to the gradient coil such that it generates the x-axis gradient field at step 1202. The eddy current magnetic field is measured at step 1204 via the sensing coil array. In some embodiments, the eddy current magnetic field is measured at each of a plurality of rotational positions to image points across a 3D volume, where the sensing coil array is rotated about a rotational axis (e.g., axis RA in FIG. 3) and measurements are made at each of several measurement positions about the axis. The eddy current magnetic field for the x-axis gradient field is characterized at step 1206. These steps are repeated for the y-axis and z-axis gradient fields, which will be understood to be performable in an alternate order. Here, the y-axis gradient field is generated at step 1208 and the eddy current magnet field is measured by the sensing coil array at step 1210, such as at each of a plurality of rotational positions about a rotational axis to gather measurement data in the 3D volume. The eddy current magnetic field characterization values for the y-axis magnetic field are generated at step 1212. The z-axis gradient field is generated at step 1214 and the eddy current magnet field is measured by the sensing coil array at step 1216, such as at each of a plurality of rotational positions about a rotational axis to gather measurement data in the 3D volume. The eddy current magnetic field characterization values for the z-axis magnetic field are generated at step 1218, including high spatial-order harmonic analysis and time constant fitting. The characterization values for the x, y, and z-axis gradient fields are then outputted and stored, such as stored in association with the model number or other identifying information of the component (here, the particular gradient coil) for use in image reconstruction, etc.

It should be understood that the above-described steps of the processes of FIG. 12 can be executed or performed in any suitable order or sequence not limited to the order and sequence shown and described in the figures. For example, the gradient fields can be tested in a different order. Also, some of the above processing steps of FIG. 12 can be executed or performed substantially simultaneously where appropriate or in parallel to reduce latency and processing times.

In various embodiments, any suitable computer readable media can be used for storing instructions for performing functions and/or processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as RAM, Flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, or any suitable media that is fleeting and devoid of any semblance of permanence during transmission, and/or any suitable intangible media.

This written description uses examples to disclose the invention(s), including the best mode, and also to enable any person skilled in the art to make and use the invention(s). Certain terms have been used for brevity, clarity, and understanding. No unnecessary limitations are to be inferred therefrom beyond the requirement of the prior art because such terms are used for descriptive purposes only and are intended to be broadly construed. The patentable scope of the invention(s) is defined by the claims and may include other examples that occur to those skilled in the art. Such other examples are intended to be within the scope of the claims if they have features or structural elements that do not differ from the literal language of the claims, or if they include equivalent features or structural elements with insubstantial differences from the literal languages of the claims.

What is claimed is:

1. A system for measuring gradient-induced eddy currents generated by an MRI system component configured to be located in or near an MRI gradient coil, the system comprising:
a current driver configured to deliver a driving current to the MRI gradient coil;
a sensing coil array configured to measure an eddy current magnetic field from the MRI system component while the driving current is delivered to the gradient coil, the sensing coil array comprising a plurality of pickup coils each configured to generate a voltage signal indicative of the eddy current magnetic field at a location of the respective pickup coil;
one or more processors configured to:
characterize the eddy current magnetic field from the MRI system component based on the voltage signal generated by each of the plurality of pickup coils and the driving current delivered to the MRI gradient coil; and
output the eddy current magnetic field characterization.

2. The system of claim 1 configured to characterize the eddy current magnetic field from the MRI system component when the gradient coil and the MRI system component are not located in the MRI main magnet.

3. The system of claim 1, wherein the one or more processors are further configured to:
determine a frequency response of each of the plurality of pickup coils based on the voltage signal; and
characterize the eddy current magnetic field based on the frequency response and the driving current delivered to the MRI system component.

4. The system of claim 1, wherein characterizing the eddy current magnetic field includes determining a spatial harmonic component of the eddy current magnetic field and at least one time constant of the spatial harmonic component.

5. The system of claim 1, wherein characterizing the eddy current magnetic field includes determining at least one time constant of the eddy current magnetic field measured by each of the plurality of pickup coils.

6. The system of claim 1, wherein the eddy current magnetic field measured by the sensing coil array is generated by short time constant eddy currents.

7. The system of claim 6, wherein the short time constant eddy currents have a time constant that is greater than 1 microsecond and less than 1 millisecond.

8. The system of claim 1, wherein the plurality of pickup coils includes at least 10 pickup coils.

9. The system of claim 1, wherein the MRI system component is a gradient coil configured to be placed in a bore of the MRI system or located outside an MRI magnet as a standalone gradient coil.

10. The system of claim 9, wherein the current driver is configured to separately drive the gradient coil to generate each of an x-axis gradient field, a y-axis gradient field, and a z-axis gradient field; and
wherein the one or more processors are further configured to separately characterize the eddy current magnetic field in the MRI system component for each of the x-axis gradient field, the y-axis gradient field, and the z-axis gradient field.

11. The system of claim 1, wherein the one or more processors is further configured to:
receive the voltage signal from each of the plurality of pickup coils at a plurality of rotational positions as the sensing coil array is rotated about an axis; and
characterize the eddy current magnetic field based on the voltage signal from each of the plurality of pickup coils at each of the plurality of rotational positions.

12. The system of claim 11, wherein the sensing coil array includes the plurality of pickup coils arranged in a circle.

13. The system of claim 11, wherein the sensing coil array includes the plurality of pickup coils arranged in a plane, wherein the axis of rotation is through a center the sensing coil array, and wherein the plurality of rotational positions are distributed across 180 degrees about the axis.

14. A method for characterizing gradient-induced eddy currents generated by an MRI system component configured to be located in or near an MRI gradient coil during imaging, the method comprising:
delivering a driving current to the MRI gradient coil to cause the MRI gradient coil to generate a primary magnetic field, wherein the primary magnetic field causes eddy currents in the MRI system component that generate an eddy current magnetic field;
measuring the eddy current magnetic field in the MRI system component with a plurality of pickup coils, wherein each pickup coil is configured to generate a voltage signal indicative of the eddy current magnetic field at a location of the respective pickup coil;
characterizing the eddy current magnetic field from the MRI system component based on the voltage signal generated by each of the plurality of pickup coils and the driving current delivered to the MRI gradient coil; and
storing the eddy current magnetic field characterization.

15. The method of claim 14, wherein the steps of delivering the driving current and measuring the eddy current magnetic field are conducted when the gradient coil and the MRI system component are not located in an MRI main magnet.

16. The method of claim 14, further comprising:
determining a frequency response of each of the plurality of pickup coils based on the voltage signal; and
characterizing the eddy current magnetic field based on the frequency response and the driving current delivered to the MRI system component.

17. The method of claim 14, wherein characterizing the eddy current magnetic field includes determining a spatial harmonic component of the eddy current magnetic field and at least one time constant of the spatial harmonic component.

18. The method of claim 14, wherein characterizing the eddy current magnetic field includes determining at least one time constant of the eddy current magnetic field measured by each of the plurality of pickup coils.

19. The method of claim 14, wherein the MRI system component is a gradient coil configured to be placed in a bore of the MRI system or located outside an MRI main magnet as a standalone gradient coil, and wherein the method further comprises:
driving the gradient coil to generate each of an x-axis gradient field, a y-axis gradient field, and a z-axis gradient field;
measuring the eddy current magnetic field from the MRI system component with the plurality of pickup coils for each of the x-axis gradient field, the y-axis gradient field, and the z-axis gradient field; and
separately characterizing the eddy current magnetic field from the MRI system component for each of the x-axis gradient field, the y-axis gradient field, and the z-axis gradient field.

20. The method of claim 14, further comprising:
rotating the plurality of pickup coils to a plurality of rotational positions near the MRI system component;
receiving the voltage signal from each of the plurality of pickup coils at each of the plurality of rotational positions as plurality of sensing coils are rotated about an axis; and
characterizing the eddy current magnetic field based on the voltage signal from each of the plurality of pickup coils at each of the plurality of rotational positions.
